(19) United States
(12) Patent Application Publication
(10) Pub. No.: US 2024/0363389 A1
(43) Pub. Date: Oct. 31, 2024

(54) MASS TRANSFER DEVICE WITH PNEUMATIC NEEDLES

(71) Applicants: Beijing Institute of Petrochemical Technology, Beijing (CN); Beijing Haiju Electronic Technology Co., Ltd., Beijing (CN)

(72) Inventors: Qiang LIU, Beijing (CN); Deshu NIU, Beijing (CN); Kaiyi WANG, Beijing (CN); Peilan PENG, Beijing (CN)

(73) Assignees: Beijing Institute of Petrochemical Technology, Beijing (CN); Beijing Haiju Electronic Technology Co., Ltd., Beijing (CN)

(21) Appl. No.: 18/387,059

(22) Filed: Nov. 6, 2023

(30) Foreign Application Priority Data
Apr. 27, 2023 (CN) 202310473276.0

(51) Int. Cl. H01L 21/683; H01L 21/687

(52) U.S. Cl. CPC H01L 21/6838; H01L 21/68778; H01L 2221/68313

(57) ABSTRACT

A mass transfer device with pneumatic needles is disclosed, which is mainly composed of three parts: a pneumatic needle visual system, a crystal film transfer system, and a substrate transfer system; the pneumatic needle visual system comprises a marble platform, a support beam, camera mounting plates, cameras, guide rails of a needle slide component, stators of the needle slide motor, the needle slide component, a pressure regulating valve, a high-frequency piezoelectric ceramic valve, a needle connection plate and an air nozzle thimble; the crystal film transfer system comprises brackets, stators of the linear motors, limit plates, a crystal film transfer frame, a crystal film stage and a crystal film; the substrate transfer system comprises guide rails, a stator of a substrate transfer frame motor, a substrate transfer frame, a fixed plate, and a target substrate.

### CROSS REFERENCE TO RELATED APPLICATION

This application is based upon and claims foreign priority to Chinese Patent Application No. 202310473276.0, filed on Apr. 27, 2023, the entire content of which is incorporated herein by reference.

### TECHNICAL FIELD

The invention relates to a mass transfer device with pneumatic needles based on a composite support platform, especially a mass transfer device that peels the chip to the target solder joint utilizing a composite form of pneumatic-needles and uses a mechanical track to achieve a high-precision alignment of the position of the substrate and the crystal film. The invention, especially suitable for the mass transfer of Mini/Micro LED chips, has the advantages of fast chip transfer speed and high transfer yield.

### BACKGROUND

In 1897, Nobel laureate, a famous physicist and inventor Carl Braun created the first cathode ray tube (CRT), which pioneered the display technology. CRT has the advantages of a large visual angle, no bad points, high color reduction, high brightness, uniform chromaticity, short response time, and low production cost. However, it has the disadvantages of difficulties in thin design, lightweight, production in large size, and poor clarity, so CRT has gradually been eliminated. In the early 1970s, Sharp produced the world's first liquid crystal display device (LCD), and display technology entered the era of LCD. LCD technology has the advantages of low energy consumption, low radiation, less linear distortion, thin display, and small weight, but there are defects in image tailing, bad points in the screen, brightness, and contrast. The invention of OLED (Organic Light-Emitting Diode) solves the defects in LCD technology. OLED technology has the advantages of ultra-thin, bendable, high contrast, no viewing angle limit, energy saving and power saving, and no delay in the screen. However, it also has the disadvantages of short lifespan, screen burning, PWM dimming that may cause harm to the human body, low pixel density, low yield, and high price. In recent years, Mini/Micro LED display technology has emerged as a new force. Mini/Micro LED display screen is formed by a plurality of micron LEDs through independent packaging to form a single pixel point. It has incomparable advantages in luminous efficiency, power consumption, contrast, response speed, lifespan, and so on. It is the best choice for the next generation of mainstream display screens.

The production process of Mini/Micro LED display mainly includes chip preparation, mass transfer, detection and repair, etc. Among them, mass transfer is to transfer millions or even tens of millions of micro LED chips from the source substrate to the target substrate accurately and efficiently. Mass transfer technology directly affects the production speed, yield, and production cost of Mini/Micro LED displays, which is the key factor restricting the mass production of LED displays. Up to now, scholars at home and abroad have proposed a variety of microchip transfer solutions, including precision picking, self-component, roller transfer, needle transfer, and laser stripping.

The precise picking technology picks up the LED chip from the source substrate and transfers it to the target substrate by adjusting the suction of the nozzle of the transfer head. A transfer device, Micro-LED grain and transfer method was disclosed in granted US201910036356.3. The chip was picked up from the source substrate by electromagnetic suction, and the chip was transferred to the target substrate by horizontal motion. The transfer accuracy is high, but the transfer efficiency is difficult to improve due to the large movement stroke of the chip.

In order to improve the transfer efficiency, the directional self-component technology uses the guidance of fluid or magnetic force to increase the transfer speed through a single mass transfer chip. A Micro-LED transfer method and device was disclosed in patent application No. 202110551123.4. An ultrasonic oscillator was used to evenly distribute the chips in the liquid of a preset box, and then the chips flow into the transfer box with the liquid, which can realize the batch transfer of the chips. However, due to the irregular movement of the chips in the liquid, the collision among the chips is caused, and the actual transfer yield is reduced.

In order to reduce the impact damage of the chip and improve the transfer yield, the roller transfer printing technology completes the co-alignment and imprinting of a large number of chips and the target substrate through the precise automation device of the roller to the roller or the opposite side of the roller. A precise and stable chip transfer method was disclosed in grant US202110651485.0. The chip was aligned with the target crystal site through image recognition, and the bulk transfer of the chip was realized by imprinting through the adhesion gradient of the two materials. However, the process of high-precision pressure control is difficult. The alignment of the chip and the target substrate cannot be determined in real-time, and the transfer accuracy is difficult to improve.

In order to improve the alignment accuracy and reduce the difficulty of the transfer process, the laser stripping technology uses a short pulse laser with high energy density and high power density to irradiate the substrate or transparent substrate with a sacrificial layer. The chemical or photothermal reaction of the sacrificial layer causes the chip to fall off onto the target substrate directly below. A laser welding unit and LED chip batch transfer bonding device and method are disclosed in granted U.S. Pat. No. 202110819686.7, which achieved a precise alignment with the target substrate with the help of image vision real-time chip. The sacrificial layer was decomposed by laser irradiation, and the chip was selectively driven to the target substrate. The selective transfer chip had a high transfer speed. However, the laser generator is expensive, which raises the production cost, and the gas generated by the decomposition of the sacrificial layer leads to the divergence of the chip transfer direction, which makes the chip prone to attitude change and position offset, and reduces the chip transfer yield.

The above transfer methods are limited by the lack of technical maturity, and the chip transfer accuracy or yield is difficult to meet the actual production needs. At present, the mainstream transfer method is needle transfer. By moving the needle transfer head up and down, the chip is pierced from the source crystal film to the target substrate, and the transfer cost is low. A needle die bonder described in U.S. Pat. No. 202222376287.0 uses a driving mechanism to drive the needle to move to realize the transfer of the chips from the source substrate to the target substrate, which has good transfer accuracy and yield. However, in the needle transfer process, the needles are in contact with the chips, and the needles produce great pressure on the chips. The internal stress is easy to produce inside the chip, and then damage is caused to the chip.

In order to reduce the stress damage in the chip, the pneumatic transfer solution is realized by blowing air through the air nozzle, so that the elastic layer of the source crystal film attached to the source substrate is bulged, which pushes the chip to peel off to the target substrate. It avoids the generation of the stress of the chip during the needle transfer process and improves the working life of the chip. A pneumatic Mass transfer device and method based on a micro-hole array was disclosed in U.S. Pat. No. 202210968918.X, and a pneumatic mass transfer solution based on a micro-hole array was proposed The micro-hole of the source substrate was blown by the air nozzle array, and the chip was transferred from the source substrate to the target substrate by using the bulge of the source crystal film. However, the rebound of the source crystal film is slow, which limits the improvement of the transfer speed.

### SUMMARY

The technical problem solved by the invention is to overcome the shortcomings of the existing technology, and a mass transfer device with pneumatic needles is proposed, which drive the chip to move quickly by using the needles with the help of a high-pressure gas flexible contact chip, a large deformation of the crystal film is used to rebound quickly, the device has the characteristics of high transfer efficiency, high transfer yield, and no damage to the chips, it is especially suitable for the Mass transfer of Mini/Micro LED chips.

The technical solution of the invention is as follows: a mass transfer device with pneumatic needles, which is mainly composed of three parts: a pneumatic needle visual system, a crystal film transfer system, and a substrate transfer system; the pneumatic needle visual system mainly includes a marble platform, a support beam, a pneumatic needle visual mounting plate, a left camera mounting plate, a right camera mounting plate, a left camera, a right camera, a left guide rail of a needle slide component, a right guide rail of the needle slide component, a stator of a needle slide motor, the needle slide component, a Z-direction grating ruler, a pressure regulating valve, a high-frequency piezoelectric ceramic valve, a needle connection plate and an air nozzle thimble; the crystal film transfer system mainly includes a left bracket, a right bracket, a left outer guide rail, a left inner guide rail, a right outer guide rail, a right inner guide rail, a stator of a left linear motor, a stator of a right linear motor, a left front limit plate, a right front limit plate, a crystal film transfer frame, an upper X-direction grating ruler, a crystal film stage, a crystal film and an upper Y-direction grating ruler; the substrate transfer system mainly includes a left guide rail, a right guide rail, a stator of a substrate transfer frame motor, a substrate transfer frame, a fixed plate, a target substrate, a lower Y-direction grating ruler and a lower X-direction grating ruler; the marble platform is located below the support beam and the pneumatic needle visual mounting plate, the support beam is located above the marble platform and is installed on an upper surface of the marble platform through fastening screws, the pneumatic needle visual mounting plate is located at a center of a front surface of a horizontal beam of the support beam and is installed on the support beam through fastening screws, the left camera mounting plate and the right camera mounting plate are symmetrically distributed on both sides of a center line of an upper surface of the pneumatic needle visual mounting plate, and are installed on the pneumatic needle visual mounting plate through fastening screws, the left camera is located in a mounting hole of the left camera mounting plate, and the right camera is located in a mounting hole of the right camera mounting plate, the left guide rail of the needle slide component and the right guide rail of the needle slide component are symmetrically distributed on both sides of the center line of the upper surface of the pneumatic needle visual mounting plate, the left guide rail of the needle slide component is located on a right side of the left camera mounting plate, and is installed on the pneumatic needle visual mounting plate through fastening screws, the right guide rail of the needle slide component is located on a left side of the right camera mounting plate, and is installed on the pneumatic needle visual mounting plate through fastening screws, the stator of the needle slide motor is located at the center line of the upper surface of the pneumatic needle visual mounting plate, the stator of the needle slide motor is located between the left guide rail of the needle slide component and the right guide rail of the needle slide component, and is installed on the pneumatic needle visual mounting plate through fastening screws, the needle slide component is located in front of the left guide rail of the needle slide component and the right guide rail of the needle slide component, and is stuck on the left guide rail of the needle slide component and the right guide rail of the needle slide component through a slider at a bottom of the needle slide component, the Z-direction grating ruler is located on a right side of the right guide rail of the needle slide component, and is pasted on the right guide rail of the needle slide component through an epoxy resin adhesive, a reading head of the Z-direction grating ruler is located on an edge of a right surface of the needle slide component, and is installed on the needle slide component through fastening screws, the pressure regulating valve and the high-frequency piezoelectric ceramic valve are located on an upper left side of a front surface of the needle slide component, the pressure regulating valve is located above the high-frequency piezoelectric ceramic valve, the needle connection plate is located at a center of the front surface of the needle slide component and is installed on the needle slide component through fastening screws, the air nozzle thimble is located in a round hole of the needle connection plate, the left bracket and the right bracket are located on the left side and the right side of the upper surface of the marble platform, respectively, the left bracket and the right bracket are located inside the support beam, the left bracket and the right bracket are located outside the pneumatic needle visual mounting plate and are installed on the marble platform through fastening screws, the left outer guide rail and the left inner guide rail are symmetrically distributed on an upper surface of the left bracket and are installed on the left bracket through fastening screws, the right outer guide rail and the right inner guide rail are symmetrically distributed on an upper surface of the right bracket, and are installed on the right bracket by fastening screws, the stator of the left linear motor is located on the upper surface of the left bracket, and the stator of the left linear motor is located between the left outer guide rail and the left inner guide rail, the stator of the right linear motor is located on the upper surface of the right bracket, the stator of the right linear motor is located between the right outer guide rail and the right inner guide rail, and is installed on the right bracket by fastening screws, the left front limit plate is located on an upper end of the front surface of the left bracket, and is installed on the left bracket by fastening screws, the right front limit plate is located on an upper end of the front surface of the right bracket, and is installed on the right bracket by fastening screws, the crystal film transfer frame is located above the left outer guide rail, left inner guide rail, right outer guide rail and right inner guide rail, the crystal film transfer frame is located below the pneumatic needle visual mounting plate and is stuck on the left outer guide rail, the left inner guide rail, the right outer guide rail and the right inner guide rail through a slider on a bottom plate of the crystal film transfer frame, the upper X-direction grating ruler is located on an upper edge of a right surface of the left bracket, and is fixed on the left bracket through the epoxy resin adhesive, a reading head of the upper X-direction grating ruler is located on a left side of a front surface of the crystal film transfer frame, and the reading head of the upper X-direction grating ruler is located on a right side of the left bracket, and is installed on the crystal film transfer frame through fastening screws, the crystal film stage is located above the crystal film transfer frame, and the crystal film stage is located below the pneumatic needle visual mounting plate and is stuck on the guide rail of the crystal film transfer frame by a slider at a bottom of the crystal film stage, and the crystal film is installed in a slot of the crystal film stage, the upper Y-direction grating ruler is located on an inner upper surface of a front baffle of the crystal film stage, and is fixed on the crystal film stage by the epoxy resin adhesive, a reading head of the upper Y-direction grating ruler is located on a front edge of an upper surface of the crystal film stage, and the reading head of the upper Y-direction grating ruler is located behind the upper Y-direction grating ruler and is installed on the crystal film stage by fastening screws, the left guide rail and the right guide rail are symmetrically distributed on both sides of the center line of the upper surface of the marble platform, the left guide rail and the right guide rail are located on the inner side of the left bracket and the right bracket, and are installed on the marble platform through fastening screws, the stator of the substrate transfer frame motor is located at the center line of the upper surface of the marble platform, the stator of the substrate transfer frame motor is located between the left guide rail and the right guide rail, and is installed on the marble platform through fastening screws, the substrate transfer frame is located above the left guide rail and the right guide rail, the substrate transfer frame is located below the crystal film transfer frame, and is stuck on the left guide rail and the right guide rail through a slider at a bottom of the substrate transfer frame, the fixed plate is located above the substrate transfer frame and is stuck on the guide rail of the substrate transfer frame through a slider at a bottom of the fixed plate, the target substrate is installed in a slot above the fixed plate, the lower Y-direction grating ruler is located on a front surface of the substrate transfer frame, and is pasted on the substrate transfer frame by the epoxy resin adhesive, the reading head of the lower Y-direction grating ruler is located at a center of a front surface of the fixed plate and is installed on the fixed plate by fastening screws, the lower X-direction grating ruler is located on the right side of the right guide rail and is pasted on the right guide rail by the epoxy resin adhesive, the reading head of the lower X-direction grating ruler is located on an edge of a right surface of the substrate transfer frame and is installed on the substrate transfer frame by fastening screws.

The needle slide component includes a main body of the needle slide component, a left upper slider, a left lower slider, a right upper slider, a right lower slider, and a mover of the needle slide motor.

The air nozzle thimble includes a gas path joint, an upper needle insertion rod, a lower needle insertion rod, and a needle.

The crystal film includes an elastic film, a viscous layer, and a chip.

The pressure regulating valve, high-frequency piezoelectric ceramic valve, and air nozzle thimble are interconnected, and an external gas pressure is from 0.1 Mpa to 3 Mpa.

The air nozzle thimble can be lowered and close to the crystal film, and the air nozzle thimble is continuously ventilated during a descent process, the working gap between a lower end of the air nozzle thimble and an upper surface of the crystal film is 0.1 mm-0.8 mm.

The air nozzle thimble pierced into the crystal film is below the horizontal line of the crystal film, bubbles will be generated between the air nozzle thimble and the crystal film under an action of air pressure, and a height of the bubbles is from 0.05 mm to 0.3 mm.

A surface of a solder joint of the target substrate is coated with bonding materials, including solder paste, flux, conductive adhesive, ACP, and ACF.

The elastic film is one of the PDMS, TPE, TPEE, TPU, TPR, TPV, PO, and PVC materials with excellent recoverable deformation ability, a convex deformation can be generated during a transfer process, so that a transferred chip is in contact with the target substrate (27), but it will not affect the chips at adjacent positions, the convex deformation can be quickly restored after the transfer is completed.

The viscous layer is one of silicone adhesive, epoxy resin adhesive, polyurethane adhesive, and acrylic adhesive, and its adhesion to the chip is less than that of the bonding material to the chip.

The principle of the above solution is as follows: As shown in FIG. 1, a mass transfer device with pneumatic needles uses a camera to scan and record the position of the chip on the source substrate and the position of the pad on the target substrate and uses a mechanical guide rail to drive the source substrate and the target substrate to move to the position below the air nozzle thimble, so as to realize vertical collinearity of the air nozzle thimble, the chip, and the solder joint. The pneumatic needle component is used to realize the piercing and lifting action of the air nozzle thimble, and the air nozzle thimble always maintains a high-pressure blowing during the transfer process. When the nozzle thimble drops to the point where it is about to touch the chip film, a small air film is generated between the air nozzle thimble and the chip, which pushes the source crystal film to bulge downward so that the lower surface of the chip contacts the solder paste on the target substrate. When the adhesion of the solder paste to the chip is greater than the adhesion of the lower surface of the source crystal film to the chip, the chip is transferred to the target substrate by means of the difference between the adhesion of the lower surface of the source crystal film and the solder paste to the chip.

Compared with the existing technology, the advantage of the invention is that the chip is transferred from the source crystal film to the target substrate by a dual drive of pneumatics and needles. Compared with the needle transfer solution, the air is used to drive the crystal film bulge, so as to avoid direct contact between the needle and the chip, eliminate the contact stress of the chip, and improve the working life of the chip. Compared with the pneumatic transfer solution, the needle-driven source crystal film is used to generate a large deformation, which increases the rebound force of the crystal film, shortens the rebound time of the crystal film, and improves the transfer speed and chip transfer efficiency of a single chip.

### BRIEF DESCRIPTION OF THE DRAWINGS

FIG. 1 is a structure diagram of the technical solution in the invention.

FIG. 2 is a three-dimensional structure diagram of the pneumatic needle visual system of the technical solution in the invention.

FIG. 3 is a three-dimensional structure diagram of the crystal film transfer system of the technical solution in the invention.

FIG. 4 is a three-dimensional structure diagram of the substrate transfer system of the technical solution in the invention.

FIG. 5 is a three-dimensional back-view structure diagram of the needle slide component of the technical solution in the invention.

FIG. 6A is a three-dimensional structure diagram of the air nozzle thimble of the technical solution in the invention.

FIG. 6B is a cross-sectional view of the air nozzle thimble of the technical solution in the invention.

FIG. 7 is a schematic diagram of the structure of the crystal film of the technical solution in the invention.

FIG. 8 is a schematic diagram of the relative position of the air nozzle thimble, the crystal film, and the target substrate during the operation of the technical solution in the invention.

### DETAILED DESCRIPTION OF THE EMBODIMENTS

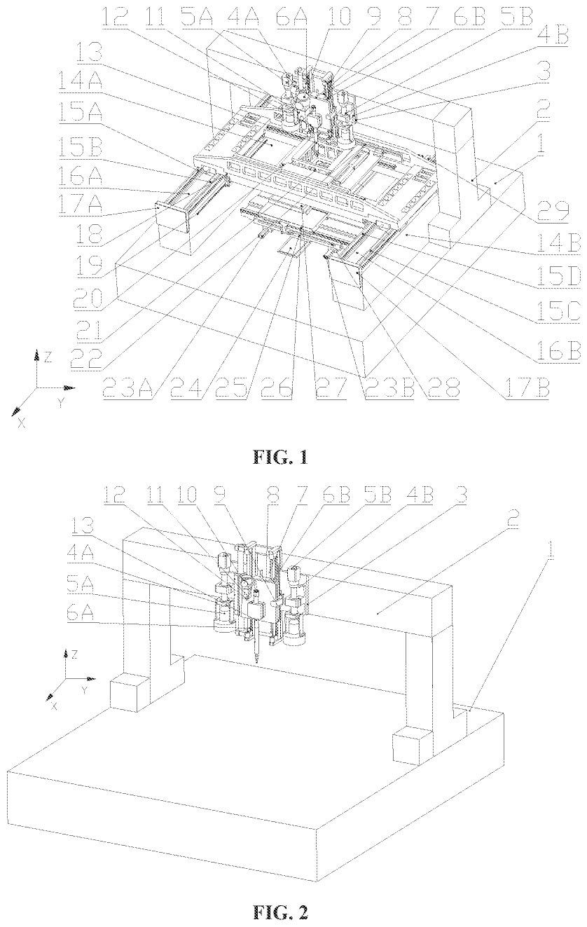

As shown in FIG. 1, it is a structural schematic diagram of the technical solution of the invention. A mass transfer device with pneumatic needles is mainly composed of a pneumatic needle visual system, a crystal film transfer system, and a substrate transfer system; the pneumatic needle visual system mainly includes a marble platform 1, a support beam 2, a pneumatic needle visual mounting plate 3, a left camera mounting plate 4A, a right camera mounting plate 4B, a left camera 5A, a right camera 5B, a left guide rail of a needle slide component 6A, a right guide rail of the needle slide component 6B, a stator of a needle slide motor 7, the needle slide component 8, a Z-direction grating ruler 9, a pressure regulating valve 10, a high-frequency piezoelectric ceramic valve 11, a needle connection plate 12 and an air nozzle thimble 13; the crystal film transfer system mainly includes a left bracket 14A, a right bracket 14B, a left outer guide rail 15A, a left inner guide rail 15B, a right outer guide rail 15C, a right inner guide rail 15D, a stator of a left linear motor 16A, a stator of the right linear motor 16B, a left front limit plate 17A, a right front limit plate 17B, a crystal film transfer frame 18, an upper X-direction grating ruler 19, a crystal film stage 20, a crystal film 21 and an upper Y-direction grating ruler 22; the substrate transfer system mainly includes a left guide rail 23A, a right guide rail 23B, a stator of a substrate transfer frame motor 24, a substrate transfer frame 25, a fixed plate 26, a target substrate 27, a lower Y-direction grating ruler 28 and a lower X-direction grating ruler 29; the marble platform 1 is located below the support beam 2 and the pneumatic needle visual mounting plate 3, the support beam 2 is located above the marble platform 1 and is installed on an upper surface of the marble platform 1 through fastening screws, the pneumatic needle visual mounting plate 3 is located at a center of a front surface of a horizontal beam of the support beam 2 and is installed on the support beam through fastening screws, the left camera mounting plate 4A and the right camera mounting plate 4B are symmetrically distributed on both sides of a center line of an upper surface of the pneumatic needle visual mounting plate 3, and are installed on the pneumatic needle visual mounting plate 3 through fastening screws, the left camera 5A is located in a mounting hole of the left camera mounting plate 4A, and the right camera 5B is located in a mounting hole of the right camera mounting plate 4B, the left guide rail 6A of the needle slide component and the right guide rail 6B of the needle slide component are symmetrically distributed on both sides of the center line of the upper surface of the pneumatic needle visual mounting plate 3, the left guide rail 6A of the needle slide component is located on a right side of the left camera mounting plate 4A, and is installed on the pneumatic needle visual mounting plate 3 through fastening screws, the right guide rail 6B of the needle slide component is located on a left side of the right camera mounting plate 5B, and is installed on the pneumatic needle visual mounting plate 3 through fastening screws, the stator of the needle slide motor 7 is located at the center line of the upper surface of the pneumatic needle visual mounting plate 3, the stator of the needle slide motor 7 is located between the left guide rail 6A of the needle slide component and the right guide rail 6B of the needle slide component, and is installed on the pneumatic needle visual mounting plate 3 through fastening screws, the needle slide component 8 is located in front of the left guide rail 6A of the needle slide component and the right guide rail 6B of the needle slide component, and is stuck on the left guide rail 6A of the needle slide component and the right guide rail 6B of the needle slide component through a slider at a bottom of the needle slide component 8, the Z-direction grating ruler 9 is located on a right side of the right guide rail 6B of the needle slide component, and is pasted on the right guide rail 6B of the needle slide component through an epoxy resin adhesive, a reading head of the Z-direction grating ruler 9 is located on an edge of a right surface of the needle slide component 8, and is installed on the needle slide component 8 through fastening screws, the pressure regulating valve 10 and the high-frequency piezoelectric ceramic valve 11 are located on an upper left side of a front surface of the needle slide component 8, the pressure regulating valve 10 is located above the high-frequency piezoelectric ceramic valve 11, the needle connection plate 12 is located at a center of the front surface of the needle slide component 8 and is installed on the needle slide component 8 through fastening screws, the air nozzle thimble 13 is located in a round hole of the needle connection plate 12, the left bracket 14A and the right bracket 14B are located on the left side and the right side of the upper surface of the marble platform 1, respectively, the left bracket 14A and the right bracket 14B are located inside the support beam 2, the left bracket 14A and the right bracket 14B are located outside the pneumatic needle visual mounting plate 3 and are installed on the marble platform 1 through fastening screws, the left outer guide rail 15A and the left inner guide rail 15B are symmetrically distributed on an upper surface of the left bracket 14A and are installed on the left bracket 14A through fastening screws, the right outer guide rail 15C and the right inner guide rail 15D are symmetrically distributed on an upper surface of the right bracket 14B, and are installed on the right bracket 14B by fastening screws, the stator of the left linear motor 16A is located on the upper surface of the left bracket 14A, and the stator of the left linear motor 16A is located between the left outer guide rail 15A and the left inner guide rail 15B, the stator of the right linear motor 16B is located on the upper surface of the right bracket 14B, the stator of the right linear motor 16B is located between the right outer guide rail 15C and the right inner guide rail 15D, and is installed on the right bracket 14B by fastening screws, the left front limit plate 17A is located on an upper end of the front surface of the left bracket 14A, and is installed on the left bracket 14 by fastening screws, the right front limit plate 17B is located on an upper end of the front surface of the right bracket 14B, and is installed on the right bracket 14B by fastening screws, the crystal film transfer frame 18 is located above the left outer guide rail 15A, left inner guide rail 15B, right outer guide rail 15C and right inner guide rail 15D, the crystal film transfer frame 18 is located below the pneumatic needle visual mounting plate 3 and is stuck on the left outer guide rail 15A, the left inner guide rail 15B, the right outer guide rail 15C and the right inner guide rail 15D through a slider on a bottom plate of the crystal film transfer frame 18, the upper X-direction grating ruler 19 is located on an upper edge of a right surface of the left bracket 14A and is fixed on the left bracket 14A through the epoxy resin adhesive, a reading head of the upper X-direction grating ruler 19 is located on a left side of a front surface of the crystal film transfer frame 18, and the reading head of the upper X-direction grating ruler 19 is located on a right side of the left bracket 14A, and is installed on the crystal film transfer frame 18 through fastening screws, the crystal film stage 20 is located above the crystal film transfer frame 18, and the crystal film stage 20 is located below the pneumatic needle visual mounting plate 3 and is stuck on the guide rail of the crystal film transfer frame 18 by a slider at a bottom of the crystal film stage 20, and the crystal film 21 is installed in a slot of the crystal film stage 20, the upper Y-direction grating ruler 22 is located on an inner upper surface of a front baffle of the crystal film stage 18, and is fixed on the crystal film stage 18 by the epoxy resin adhesive, a reading head of the upper Y-direction grating ruler 22 is located on a front edge of an upper surface of the crystal film stage 20, and the reading head of the upper Y-direction grating ruler 22 is located behind the upper Y-direction grating ruler 22 and is installed on the crystal film stage 20 by fastening screws, the left guide rail 23A and the right guide rail 23B are symmetrically distributed on both sides of the center line of the upper surface of the marble platform 1, the left guide rail 23A and the right guide rail 23B are located on the inner side of the left bracket 14A and the right bracket 14B, and are installed on the marble platform 1 through fastening screws, the stator of the substrate transfer frame motor 24 is located at the center line of the upper surface of the marble platform 1, the stator of the substrate transfer frame motor 24 is located between the left guide rail 23A and the right guide rail 23B, and is installed on the marble platform 1 through fastening screws, the substrate transfer frame 25 is located above the left guide rail 23A and the right guide rail 23B, the substrate transfer frame 25 is located below the crystal film transfer frame 18 and is stuck on the left guide rail 23A and the right guide rail 23B through a slider at a bottom of the substrate transfer frame 18, the fixed plate 26 is located above the substrate transfer frame 25 and is stuck on the guide rail of the substrate transfer frame 25 through a slider at a bottom of the fixed plate 26, the target substrate 27 is installed in a slot above the fixed plate 26, the lower Y-direction grating ruler 28 is located on a front surface of the substrate transfer frame 25, and is pasted on the substrate transfer frame 25 by the epoxy resin adhesive, the reading head of the lower Y-direction grating ruler 28 is located at a center of a front surface of the fixed plate 26 and is installed on the fixed plate 26 by fastening screws, the lower X-direction grating ruler 29 is located on the right side of the right guide rail 23B and is pasted on the right guide rail 23B by the epoxy resin adhesive, the reading head of the lower X-direction grating ruler 29 is located on an edge of a right surface of the substrate transfer frame 25 and is installed on the substrate transfer frame 25 by fastening screws.

FIG. 2 is a three-dimensional structure diagram of the pneumatic needle visual system of the technical solution in the invention. The pneumatic needle visual system mainly includes a marble platform 1, a support beam 2, a pneumatic needle visual mounting plate 3, a left camera mounting plate 4A, a right camera mounting plate 4B, a left camera 5A, a right camera 5B, a left guide rail of the needle slide component 6A, a right guide rail of the needle slide component 6B, a stator of a needle slide motor 7, the needle slide component 8, a Z-direction grating ruler 9, a pressure regulating valve 10, a high-frequency piezoelectric ceramic valve 11, a needle connection plate 12 and an air nozzle thimble 13; the marble platform 1 is located below the support beam 2 and the pneumatic needle visual mounting plate 3, the support beam 2 is located above the marble platform 1 and is installed on the upper surface of the marble platform 1 through fastening screws, the pneumatic needle visual mounting plate 3 is located at the center of the front surface of the horizontal beam of the support beam 2 and is installed on the support beam through fastening screws, the left camera mounting plate 4A and the right camera mounting plate 4B are symmetrically distributed on both sides of the center line of the upper surface of the pneumatic needle visual mounting plate 3, and are installed on the pneumatic needle visual mounting plate 3 through fastening screws, the left camera 5A is located in the mounting hole of the left camera mounting plate 4A, and the right camera 5B is located in the mounting hole of the right camera mounting plate 4B, the left guide rail 6A of the needle slide component and the right guide rail 6B of the needle slide component are symmetrically distributed on both sides of the center line of the upper surface of the pneumatic needle visual mounting plate 3, the left guide rail 6A of the needle slide component is located on the right side of the left camera mounting plate 4A, and is installed on the pneumatic needle visual mounting plate 3 through fastening screws, the right guide rail 6B of the needle slide component is located on the left side of the right camera mounting plate 5B, and is installed on the pneumatic needle visual mounting plate 3 through fastening screws, the stator of the needle slide motor 7 is located at the center line of the upper surface of the pneumatic needle visual mounting plate 3, the stator of the needle slide motor 7 is located between the left guide rail 6A of the needle slide component and the right guide rail 6B of the needle slide component, and is installed on the pneumatic needle visual mounting plate 3 through fastening screws, the needle slide component 8 is located in front of the left guide rail 6A of the needle slide component and the right guide rail 6B of the needle slide component, and is stuck on the left guide rail 6A of the needle slide component and the right guide rail 6B of the needle slide component through the slider at the bottom of the needle slide component 8, the Z-direction grating ruler 9 is located on a right side of the right guide rail 6B of the needle slide component, and is pasted on the right guide rail 6B of the needle slide component through the epoxy resin adhesive, the reading head of the Z-direction grating ruler 9 is located on an edge of a right surface of the needle slide component 8, and is installed on the needle slide component 8 through fastening screws, the pressure regulating valve 10 and the high-frequency piezoelectric ceramic valve 11 are located on the upper left side of the front surface of the needle slide component 8, the pressure regulating valve 10 is located above the high-frequency piezoelectric ceramic valve 11, the needle connection plate 12 is located at the center of the front surface of the needle slide component 8 and is installed on the needle slide component 8 through fastening screws, the air nozzle thimble 13 is located in a round hole of the needle connection plate 12.

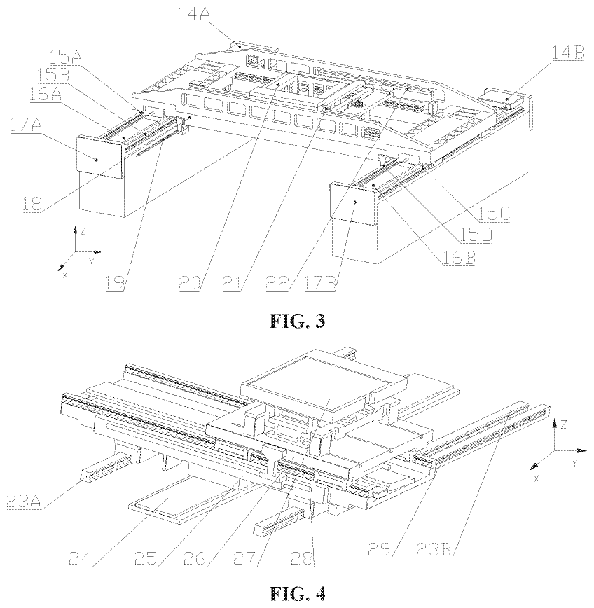

FIG. 3 is a three-dimensional structure diagram of the crystal film transfer system of the technical solution in the invention. The crystal film transfer system mainly includes a left bracket 14A, a right bracket 14B, a left outer guide rail 15A, a left inner guide rail 15B, a right outer guide rail 15C, a right inner guide rail 15D, a stator of a left linear motor 16A, a stator of the right linear motor 16B, a left front limit plate 17A, a right front limit plate 17B, a crystal film transfer frame 18, an upper X-direction grating ruler 19, a crystal film stage 20, a crystal film 21 and an upper Y-direction grating ruler 22; the left bracket 14A is located below the left outer guide rail 15A and the left inner guide rail 15B, and the right bracket 14B is located below the right outer guide rail 15C and the right inner guide rail 15D, the left outer guide rail 15A and the left inner guide rail 15B are symmetrically distributed on the upper surface of the left bracket 14A and are installed on the left bracket 14A through fastening screws, the right outer guide rail 15C and the right inner guide rail 15D are symmetrically distributed on the upper surface of the right bracket 14B, and are installed on the right bracket 14B by fastening screws, the stator of the left linear motor 16A is located on the upper surface of the left bracket 14A, and the stator of the left linear motor 16A is located between the left outer guide rail 15A and the left inner guide rail 15B, the stator of the right linear motor 16B is located on the upper surface of the right bracket 14B, the stator of the right linear motor 16B is located between the right outer guide rail 15C and the right inner guide rail 15D, and is installed on the right bracket 14B by fastening screws, the left front limit plate 17A is located on the upper end of the front surface of the left bracket 14A, and is installed on the left bracket 14 by fastening screws, the right front limit plate 17B is located on the upper end of the front surface of the right bracket 14B, and is installed on the right bracket 14B by fastening screws, the crystal film transfer frame 18 is located above the left outer guide rail 15A, left inner guide rail 15B, right outer guide rail 15C and right inner guide rail 15D, the crystal film transfer frame 18 is located below the pneumatic needle visual mounting plate 3 and is stuck on the left outer guide rail 15A, the left inner guide rail 15B, the right outer guide rail 15C and the right inner guide rail 15D through the slider on the bottom plate of the crystal film transfer frame 18, the upper X-direction grating ruler 19 is located on the upper edge of the right surface of the left bracket 14A and is fixed on the left bracket 14A through the epoxy resin adhesive, the reading head of the upper X-direction grating ruler 19 is located on the left side of the front surface of the crystal film transfer frame 18, and the reading head of the upper X-direction grating ruler 19 is located on the right side of the left bracket 14A, and is installed on the crystal film transfer frame 18 through fastening screws, the crystal film stage 20 is located above the crystal film transfer frame 18, and the crystal film stage 20 is located below the pneumatic needle visual mounting plate 3 and is stuck on the guide rail of the crystal film transfer frame 18 by the slider at the bottom of the crystal film stage 20, and the crystal film 21 is installed in the slot of the crystal film stage 20, the upper Y-direction grating ruler 22 is located on the inner upper surface of the front baffle of the crystal film stage 18, and is fixed on the crystal film stage 18 by the epoxy resin adhesive, the reading head of the upper Y-direction grating ruler 22 is located on the front edge of the upper surface of the crystal film stage 20, and the reading head of the upper Y-direction grating ruler 22 is located behind the upper Y-direction grating ruler 22 and is installed on the crystal film stage 20 by fastening screws.

FIG. 4 is a three-dimensional structure diagram of the substrate transfer system of the technical solution in the invention. The substrate transfer system mainly includes a left guide rail 23A, a right guide rail 23B, a stator of a substrate transfer frame motor 24, a substrate transfer frame 25, a fixed plate 26, a target substrate 27, a lower Y-direction grating ruler 28 and a lower X-direction grating ruler 29; the left guide rail 23A and the right guide rail 23B are symmetrically distributed on both sides of the stator of the substrate transfer frame motor 24, the stator of the substrate transfer frame motor 24 is located the center between the left guide rail 23A and the right guide rail 23B, the substrate transfer frame 25 is located above the left guide rail 23A and the right guide rail 23B, the substrate transfer frame 25 is stuck on the left guide rail 23A and the right guide rail 23B through the slider at the bottom of the substrate transfer frame 25, the fixed plate 26 is located above the substrate transfer frame 25 and is stuck on the guide rail of the substrate transfer frame 25 through the slider at the bottom of the fixed plate 26, the target substrate 27 is installed in the slot above the fixed plate 26, the lower Y-direction grating ruler 28 is located on a front surface of the substrate transfer frame 25, and is pasted on the substrate transfer frame 25 by the epoxy resin adhesive, the reading head of the lower Y-direction grating ruler 28 is located at the center of the front surface of the fixed plate 26 and is installed on the fixed plate 26 by fastening screws, the lower X-direction grating ruler 29 is located on the right side of the right guide rail 23B and is pasted on the right guide rail 23B by the epoxy resin adhesive, the reading head of the lower X-direction grating ruler 29 is located on the edge of the right surface of the substrate transfer frame 25 and is installed on the substrate transfer frame 25 by fastening screws.

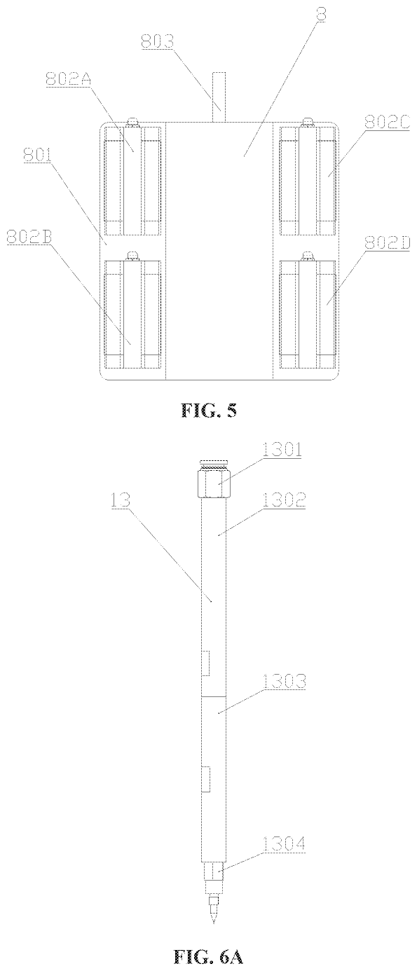

FIG. 5 is a three-dimensional back-view structure diagram of the needle slide component 8 of the technical solution in the invention. The needle slide component 8 mainly includes a main body of the needle slide component 801, a left upper slider 802A, a left lower slider 802B, a right upper slider 802C, a right lower slider 802D and a mover of the needle slide motor 803; main body of the needle slide component 801 is located in front of the left upper slider 802A, the left lower slider 802B, the right upper slider 802C, the right lower slider 802D and mover of the needle slide motor 803, the left upper slider 802A, the left lower slider 802B, the right upper slider 802C, the right lower slider 802D are respectively located at the four corners of the left upper position, left lower position, right upper position and right lower position on the back surface of the main body of the needle slide component 801 and are installed on the main body of the needle slide component 801 by fastening screws. The mover of the needle slide motor 803 is located between the left upper slider 802A, the left lower slider 802B, the right upper slider 802C, and the right lower slider 802D, and is installed on the main body of the needle slide component 801 through fastening screws.

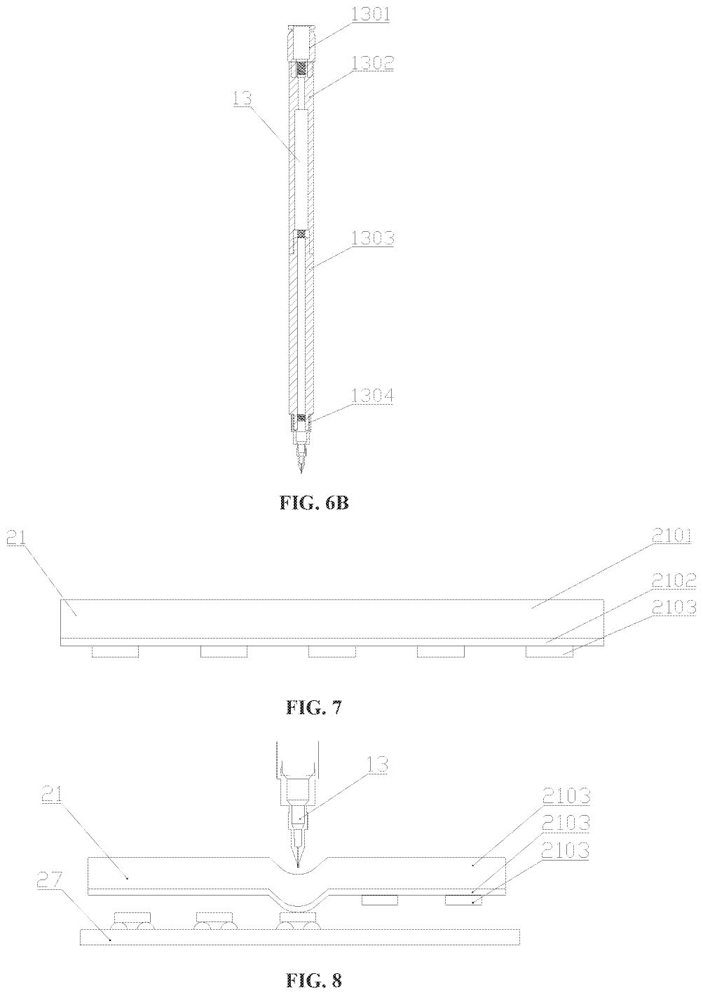

FIG. 6A is the three-dimensional structure diagram of the air nozzle thimble 13 of the technical solution in the invention. FIG. 6B is the cross-sectional view of the air nozzle thimble 13 of the technical solution in the invention. The air nozzle thimble 13 includes a gas path joint 1301, an upper needle insertion rod 1302, a lower needle insertion rod 1303, and a needle 1304, the gas path joint 1301 is located above the upper needle insertion rod 1302, the lower end of the gas path joint 1301 and the upper end of the upper needle insertion rod 1302 complete the locking connection through the thread, the lower needle insertion rod 1303 is located below the upper needle insertion rod 1302, the lower end of the upper needle insertion rod 1302 and the upper end of the lower needle insertion rod 1303 complete the locking connection through the thread, the needle 1304 is located below the lower needle insertion rod 1303, and the locking connection is completed by the lower end of the lower needle insertion rod 1303 and the upper end of the needle 1304.

FIG. 7 is a schematic diagram of the structure of the crystal film 21 of the technical solution in the invention. The crystal film 21 mainly includes an elastic film 2101, a viscous layer 2102, and a chip 2103; the elastic film 2101 is located above the viscous layer 2102, and the chip 2103 is located below the elastic film and the viscous layer 2102 and adheres to the lower surface of the viscous layer 2102 through the viscosity of the viscous layer 2102, the elastic film 2101 is one of the PDMS, TPE, TPEE, TPU, TPR, TPV, PO and PVC materials with excellent recoverable deformation ability, the convex deformation can be generated during the transfer of the elastic film 2101, so that the transferred chip 2103 is in contact with the target substrate 27, but it will not affect the chip 2103 at the adjacent position, the convex deformation can be quickly restored, the viscous layer 2102 is one of the silicone adhesive, epoxy resin adhesive, polyurethane adhesive, and acrylic adhesive, the adhesion of the viscous layer 2102 to the chip 2103 is less than that of the bonding material to the chip.

FIG. 8 is a schematic diagram of the relative position of the air nozzle thimble 13, the crystal film 21, and the target substrate 27 during the operation of the technical solution of the invention. During the transfer process, when the solder joints on the air nozzle thimble 13, the chip 2103 and the target substrate 27 complete the collinear alignment, the nozzle 13 is connected to the external gas source, and the high-pressure gas is blown out, at the same time, the air nozzle thimble 13 moves downward and penetrates below the horizontal line of the elastic film 2101, there is a gap between the lower end of the air nozzle thimble 13 and the upper surface of the elastic film 2101, which ranges from 0.1 mm to 0.8 mm, under the action of high-pressure gas, a bubble with a height of 0.05 mm-0.3 mm is generated between the air nozzle thimble 13 and the elastic film 2101, which causes the elastic film 2101 to drive the viscous layer 2102 to form a convex deformation downward, the lower surface of the chip 2103 adhered to the viscous layer 2102 contacts the bonding material on the target substrate 27, the air nozzle thimble 13 is disconnected from the external air source, at the same time, the air nozzle thimble 13 moves upward and resets, the elastic film 2101 drives the viscous layer 2102 to recover and deform upward, because the viscosity between the upper surface of the chip 2103 and the viscous layer 2102 is smaller than that between the lower surface of the chip 2103 and the solder paste bonding material, the chip 2103 peels off to the target substrate 27 to complete the transfer.

What is claimed is:

1. A mass transfer device with pneumatic needles, comprising: a pneumatic needle visual system, a crystal film transfer system, and a substrate transfer system; wherein the pneumatic needle visual system comprises a marble platform, a support beam, a pneumatic needle visual mounting plate, a left camera mounting plate, a right camera mounting plate, a left camera, a right camera, a needle slide component, a left guide rail of the needle slide component, a right guide rail of the needle slide component, a stator of a needle slide motor, a Z-direction grating ruler, a pressure regulating valve, a high-frequency piezoelectric ceramic valve, a needle connection plate, and an air nozzle thimble; the crystal film transfer system comprises a left bracket, a right bracket, a left outer guide rail, a left inner guide rail, a right outer guide rail, a right inner guide rail, a stator of a left linear motor, a stator of a right linear motor, a left front limit plate, a right front limit plate, a crystal film transfer frame, an upper X-direction grating ruler, a crystal film stage, a crystal film, and an upper Y-direction grating ruler; the substrate transfer system comprises a left guide rail, a right guide rail, a stator of a substrate transfer frame motor, a substrate transfer frame, a fixed plate, a target substrate, a lower Y-direction grating ruler, and a lower X-direction grating ruler; the marble platform is located below the support beam and the pneumatic needle visual mounting plate, the support beam is located above the marble platform and is installed on an upper surface of the marble platform through fastening screws, the pneumatic needle visual mounting plate is located at a center of a front surface of a horizontal beam of the support beam and is installed on the support beam through fastening screws, the left camera mounting plate and the right camera mounting plate are symmetrically distributed on both sides of a center line of an upper surface of the pneumatic needle visual mounting plate, and are installed on the pneumatic needle visual mounting plate through fastening screws, the left camera is located in a mounting hole of the left camera mounting plate, and the right camera is located in a mounting hole of the right camera mounting plate, the left guide rail of the needle slide component and the right guide rail of the needle slide component are symmetrically distributed on both sides of the center line of the upper surface of the pneumatic needle visual mounting plate, the left guide rail of the needle slide component is located on a right side of the left camera mounting plate, and is installed on the pneumatic needle visual mounting plate through fastening screws, the right guide rail of the needle slide component is located on a left side of the right camera mounting plate, and is installed on the pneumatic needle visual mounting plate through fastening screws, the stator of the needle slide motor is located at the center line of the upper surface of the pneumatic needle visual mounting plate, the stator of the needle slide motor is located between the left guide rail of the needle slide component and the right guide rail of the needle slide component, and is installed on the pneumatic needle visual mounting plate through fastening screws, the needle slide component is located in front of the left guide rail of the needle slide component and the right guide rail of the needle slide component, and is stuck on the left guide rail of the needle slide component and the right guide rail of the needle slide component through a slider at a bottom of the needle slide component, the Z-direction grating ruler is located on a right side of the right guide rail of the needle slide component, and is pasted on the right guide rail of the needle slide component through an epoxy resin adhesive, a reading head of the Z-direction grating ruler is located on an edge of a right surface of the needle slide component, and is installed on the needle slide component through fastening screws, the pressure regulating valve and the high-frequency piezoelectric ceramic valve are located on an upper left side of a front surface of the needle slide component, the pressure regulating valve is located above the high-frequency piezoelectric ceramic valve, the needle connection plate is located at a center of the front surface of the needle slide component and is installed on the needle slide component through fastening screws, the air nozzle thimble is located in a round hole of the needle connection plate, the left bracket and the right bracket are located on the left side and the right side of the upper surface of the marble platform, respectively, the left bracket and the right bracket are located inside the support beam, the left bracket and the right bracket are located outside the pneumatic needle visual mounting plate and are installed on the marble platform through fastening screws, the left outer guide rail and the left inner guide rail are symmetrically distributed on an upper surface of the left bracket and are installed on the left bracket through fastening screws, the right outer guide rail and the right inner guide rail are symmetrically distributed on an upper surface of the right bracket, and are installed on the right bracket by fastening screws, the stator of the left linear motor is located on the upper surface of the left bracket, and the stator of the left linear motor is located between the left outer guide rail and the left inner guide rail, the stator of the right linear motor is located on the upper surface of the right bracket, the stator of the right linear motor is located between the right outer guide rail and the right inner guide rail, and is installed on the right bracket by fastening screws, the left front limit plate is located on an upper end of the front surface of the left bracket, and is installed on the left bracket by fastening screws, the right front limit plate is located on an upper end of the front surface of the right bracket, and is installed on the right bracket by fastening screws, the crystal film transfer frame is located above the left outer guide rail, left inner guide rail, right outer guide rail and right inner guide rail, the crystal film transfer frame is located below the pneumatic needle visual mounting plate and is stuck on the left outer guide rail, the left inner guide rail, the right outer guide rail and the right inner guide rail through a slider on a bottom plate of the crystal film transfer frame, the upper X-direction grating ruler is located on an upper edge of a right surface of the left bracket, and is fixed on the left bracket through the epoxy resin adhesive, a reading head of the upper X-direction grating ruler is located on a left side of a front surface of the crystal film transfer frame, and the reading head of the upper X-direction grating ruler is located on a right side of the left bracket, and is installed on the crystal film transfer frame through fastening screws, the crystal film stage is located above the crystal film transfer frame, and the crystal film stage is located below the pneumatic needle visual mounting plate and is stuck on the guide rail of the crystal film transfer frame by a slider at a bottom of the crystal film stage, and the crystal film is installed in a slot of the crystal film stage, the upper Y-direction grating ruler is located on an inner upper surface of a front baffle of the crystal film stage, and is fixed on the crystal film stage by the epoxy resin adhesive, a reading head of the upper Y-direction grating ruler is located on a front edge of an upper surface of the crystal film stage, and the reading head of the upper Y-direction grating ruler is located behind the upper Y-direction grating ruler and is installed on the crystal film stage by fastening screws, the left guide rail and the right guide rail are symmetrically distributed on both sides of the center line of the upper surface of the marble platform, the left guide rail and the right guide rail are located on the inner side of the left bracket and the right bracket, and are installed on the marble platform through fastening screws, the stator of the substrate transfer frame motor is located at the center line of the upper surface of the marble platform, the stator of the substrate transfer frame motor is located between the left guide rail and the right guide rail, and is installed on the marble platform through fastening screws, the substrate transfer frame is located above the left guide rail and the right guide rail, the substrate transfer frame is located below the crystal film transfer frame, and is stuck on the left guide rail and the right guide rail through a slider at a bottom of the substrate transfer frame, the fixed plate is located above the substrate transfer frame and is stuck on the guide rail of the substrate transfer frame through a slider at a bottom of the fixed plate, the target substrate is installed in a slot above the fixed plate, the lower Y-direction grating ruler is located on a front surface of the substrate transfer frame, and is pasted on the substrate transfer frame by the epoxy resin adhesive, the reading head of the lower Y-direction grating ruler is located at a center of a front surface of the fixed plate and is installed on the fixed plate by fastening screws, the lower X-direction grating ruler is located on the right side of the right guide rail and is pasted on the right guide rail by the epoxy resin adhesive, the reading head of the lower X-direction grating ruler is located on an edge of a right surface of the substrate transfer frame and is installed on the substrate transfer frame by fastening screws.

2. The mass transfer device with pneumatic needles according to claim 1, wherein the needle slide component includes a main body of the needle slide component, a left upper slider, a left lower slider, a right upper slider, a right lower slider, and a mover of the needle slide motor.

3. The mass transfer device with pneumatic needles according to claim 1, wherein the air nozzle thimble includes a gas path joint, an upper needle insertion rod, a lower needle insertion rod, and a needle.

4. The mass transfer device with pneumatic needles according to claim 1, wherein the crystal film includes an elastic film, a viscous layer, and a chip.

5. The mass transfer device with pneumatic needles according to claim 1, wherein the pressure regulating valve, high-frequency piezoelectric ceramic valve, and air nozzle thimble are introduced into an external gas source, and an air pressure is 0.1 MPa-3 MPa.

6. The mass transfer device with pneumatic needles according to claim 1, wherein the pressure regulating valve, high-frequency piezoelectric ceramic valve, and air nozzle thimble are interconnected, and an external gas pressure is from 0.1 Mpa to 3 Mpa

7. The mass transfer device with pneumatic needles according to claim 1, wherein the air nozzle thimble pierced into the crystal film is below the horizontal line of the crystal film, bubbles will be generated between the air nozzle thimble and the crystal film under an action of air pressure, and a height of the bubbles is from 0.05 mm to 0.3 mm.

8. The mass transfer device with pneumatic needles according to claim 1, wherein a surface of a solder joint of the target substrate is coated with bonding materials, including solder paste, flux, conductive adhesive, ACP, and ACF.

9. The mass transfer device with pneumatic needles according to claim 6, wherein the elastic film is one of the PDMS, TPE, TPEE, TPU, TPR, TPV, PO, or PVC materials with excellent recoverable deformation ability, a convex deformation is generated during a transfer process, so that a transferred chip is in contact with the target substrate, but it will not affect the chips at adjacent positions, the convex deformation is quickly restored after the transfer is completed.

10. The mass transfer device with pneumatic needles according to claim 6, wherein the viscous layer is one of silicone adhesive, epoxy resin adhesive, polyurethane adhesive, or acrylic adhesive, and its adhesion to the chip is less than that of the bonding material to the chip.
